(19) United States
(12) Patent Application Publication
(10) Pub. No.: US 2006/0131710 A1
(43) Pub. Date: Jun. 22, 2006

(54) Advanced cavity structure for wafer level chip scale package

(75) Inventors: Chin Chen Kuo, Taipei City (TW); Jack Deng, Miaoli County (TW); Fu-Tien Weng, Hsin-Chu City (TW); Chih-Kung Chang, Hsin-Chu (TW); Bii-Jung Chang, Hsin-Chu City (TW)

Correspondence Address: BAKER & MCKENZIE;ON BEHALF OF TSMC, 2300 TRAMMELL CROW CENTER, 2001 ROSS AVENUE, SUITE 2300, DALLAS, TX, 75201, US

(73) Assignee: Taiwan Semiconductor Manufacturing Company, Ltd.

(21) Appl. No.: 11/020,041

(22) Filed: Dec. 21, 2004

(51) Int. Cl. H01L 21/00; H01L 23/02

(52) U.S. Cl. 257/678; 438/64

(57) ABSTRACT

The present invention provides an advanced cavity structure for optically sensitive devices in wafer level chip scale package and methods of manufacturing thereof. Image sensor or light detection integrated circuits are formed on substrate. Substantially absorptive bleached cavity walls are formed about the image sensor or light detection integrated circuits. Upon attaching a transparent layer to the bleached cavity walls and above the image sensor or light detection integrated circuits, open chambers are formed thereby permitting the image sensor or light detection integrated circuits to receive and manipulate signals without decreasing or decaying the optical sensitivity of the incident light. Furthermore, individual image sensor or light detection integrated circuits may be separated from each other to comprise wafer level chip scale packages of at least one image sensor or light detection integrated circuits, at least one transparent layer, and at least one open chamber.

### FIELD OF ACTIVITY

Disclosed embodiments relate to an advanced cavity structure for optically sensitive devices in wafer level chip scale package and methods of manufacturing thereof.

### BACKGROUND OF THE INVENTION

Optically sensitive devices such as image sensor and light detection integrated circuits play an important role in capturing color, image, and signal in optical electronic devices. These integrated circuits have been found in consumer electronics products and portable devices such as digital cameras, digital camcorders, and cellular phones.

One of the ways of packaging image sensor and light detection integrated circuits involves laminating silicon wafer between two glass substrates and completely encapsulating it with optical epoxy, whereby electrical contacts can be routed to the back of the silicon wafer, leaving the optically sensitive device exposed for light or image sensing applications via one of the glass substrates. The optical epoxy can, however, scatter and absorb the incident light, consequently leading to decayed and decreased optical sensitivity.

### SUMMARY OF THE INVENTION

The present invention provides an advanced cavity structure for optically sensitive devices in wafer level chip scale packages. The optically sensitive devices comprise of image sensor or light detection integrated circuits formed on a substrate. In one embodiment, bleached cavity walls are formed about the image sensor or light detection integrated circuits. In this embodiment, the bleached cavity walls are substantially absorptive of incident light.

In yet a further embodiment, a transparent layer is formed on the bleached cavity walls and above the image sensor or light detection integrated circuits thereby defining open chambers between the transparent layer, the bleached cavity walls, and the image sensor or light detection integrated circuits. In this embodiment, the open chambers may be evacuated or gaseous thereby permitting the image sensor or light detection integrated circuits to receive or manipulate signals, whether image or light, via the transparent layer through the open chamber without decreasing or decaying the optical sensitivity of the incident light.

In yet another embodiment, at least one image sensor or light detection integrated circuit, at least one transparent layer, and at least one open chamber can be individually separated from at least one image sensor or light detection integrated circuits, at least one transparent layer, and at least one open chamber to comprise the wafer level chip scale package.

### BRIEF DESCRIPTION OF THE DRAWINGS

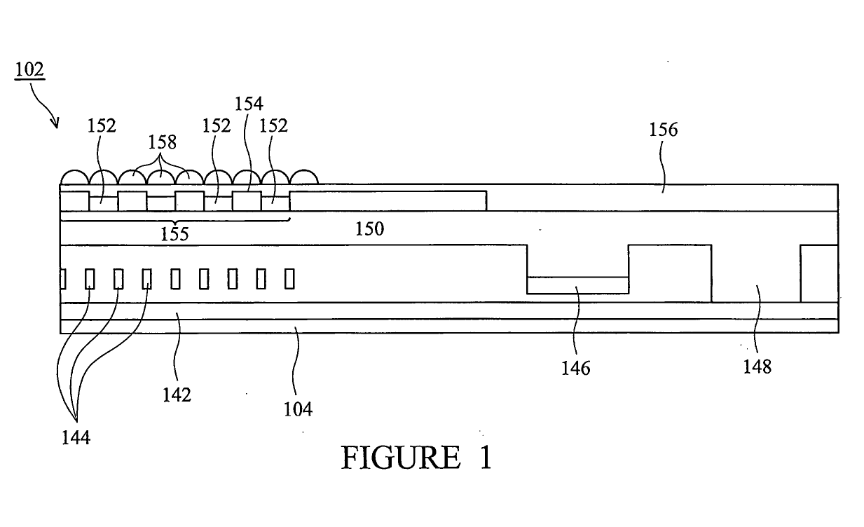

(1) FIG. 1 is the cross-sectional view of a color filter integrated circuit on a substrate;

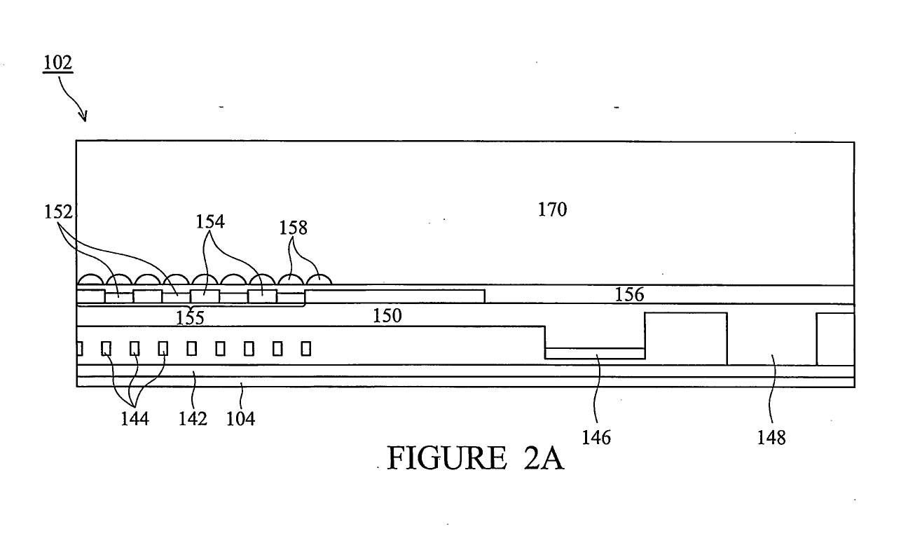

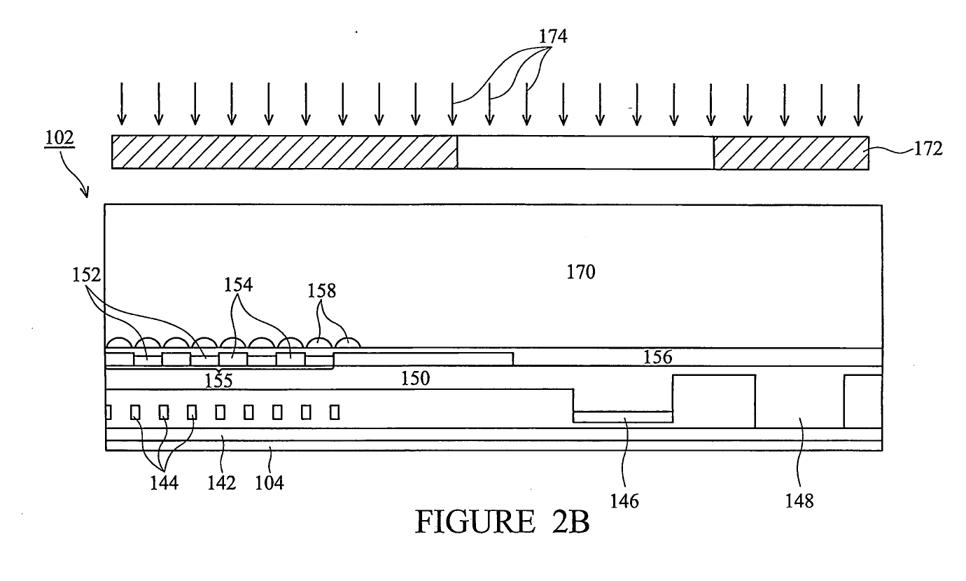

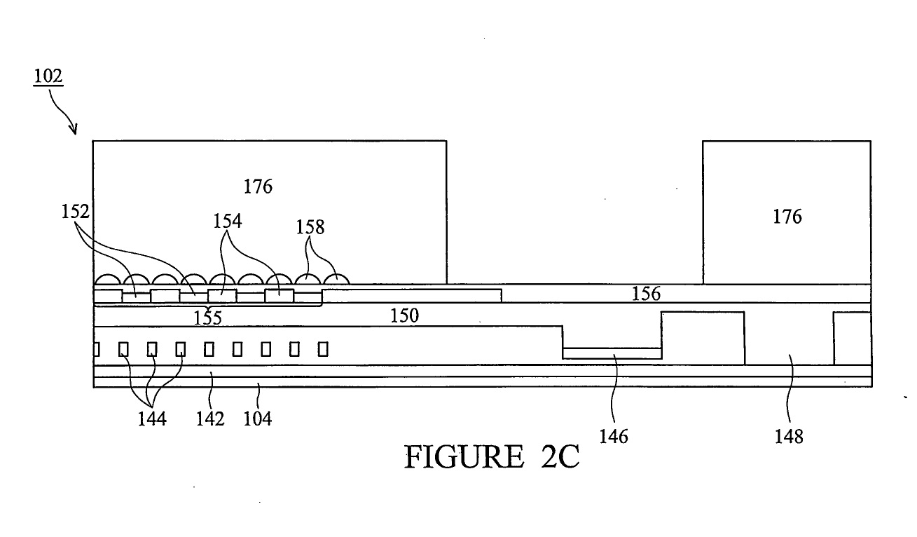

(2) FIGS. 2A-2C illustrate the steps of a conventional lithographic fabrication process with positive photoresist;

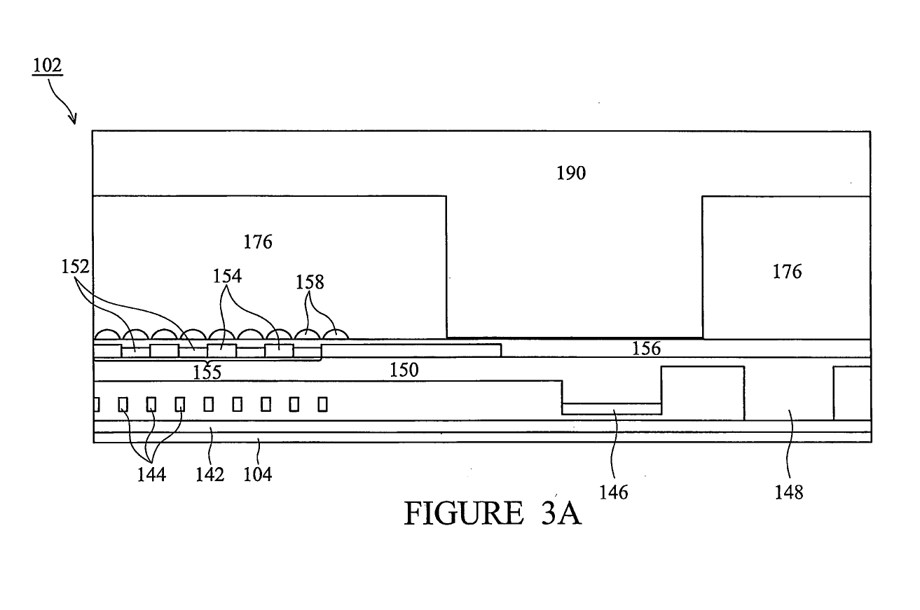

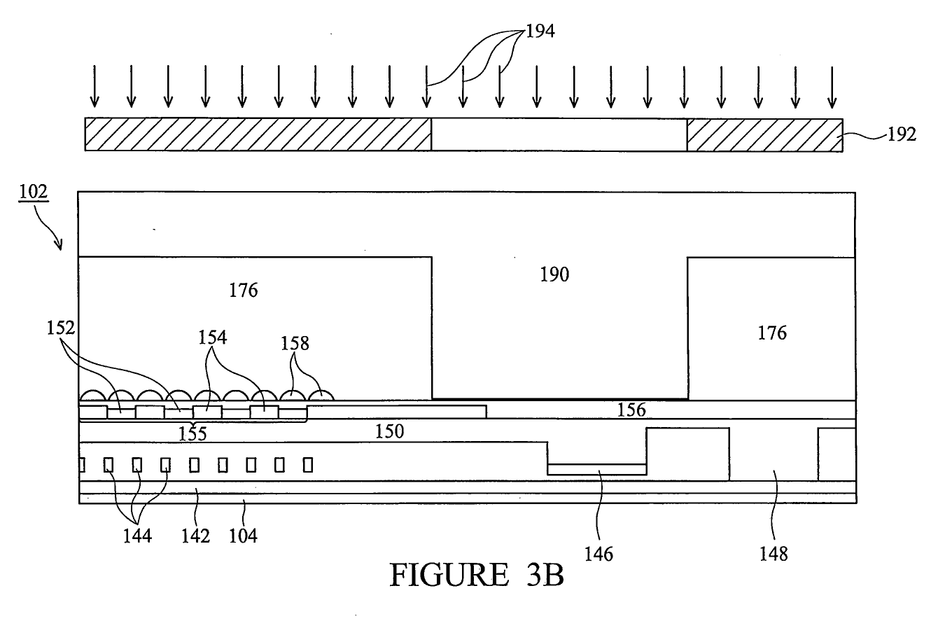

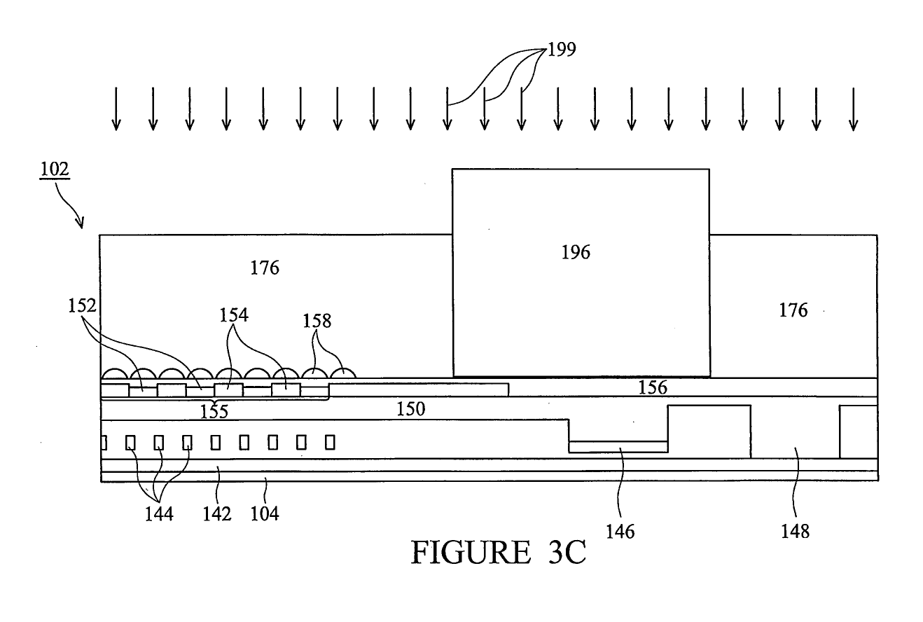

(3) FIGS. 3A-3C illustrate the steps of a conventional lithographic fabrication process with negative photoresist;

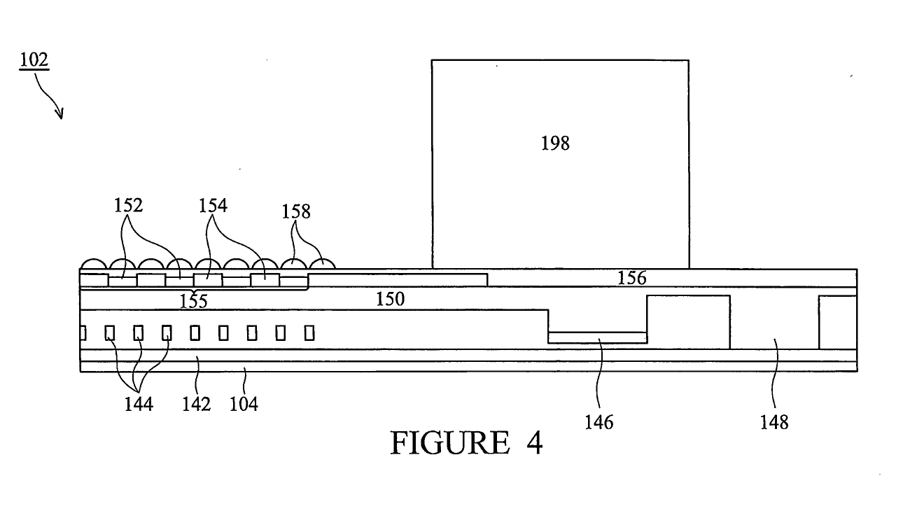

(4) FIG. 4 is an exemplary depiction of the color filter of FIG. 1 after the formation of cavity walls with bleached negative photoresist;

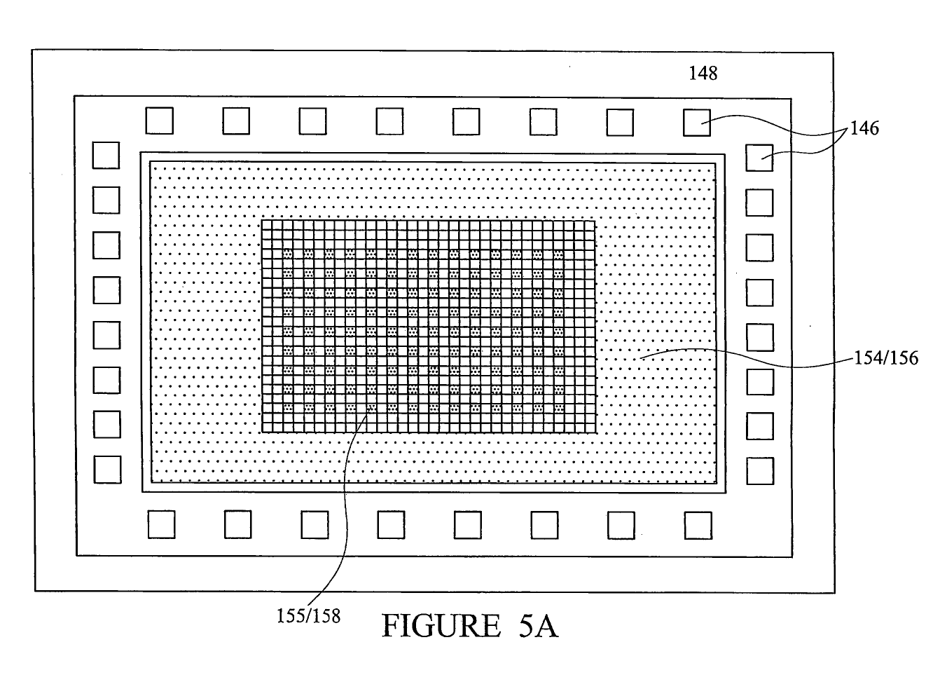

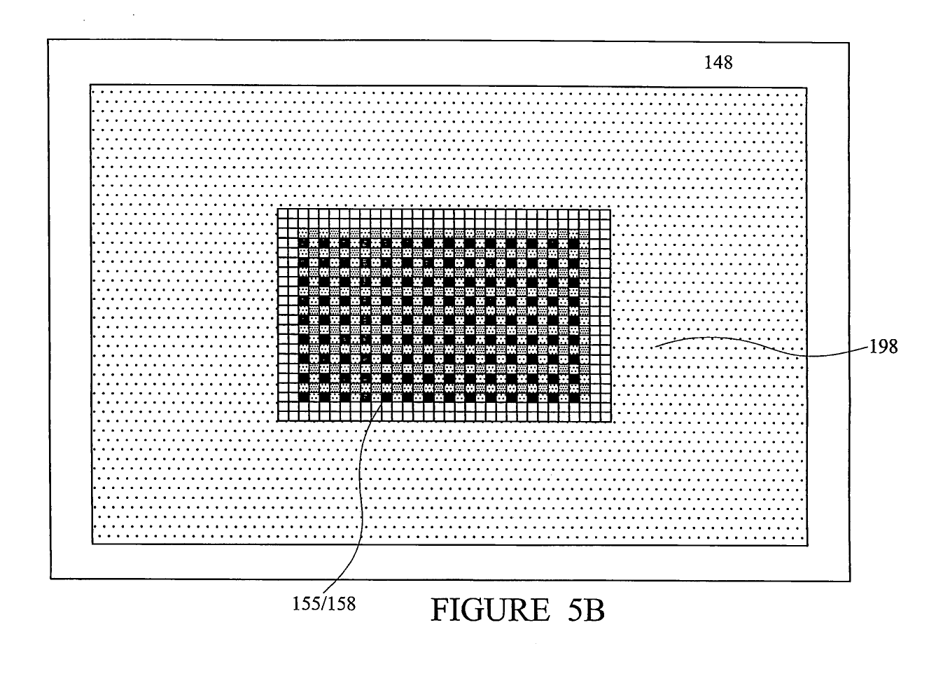

(5) FIG. 5A is an exemplary planar view of a color filter device before the formation of cavity walls with bleached negative photoresist;

(6) FIG. 5B is an exemplary planar view of a color filter device after the formation of cavity walls with bleached negative photoresist;

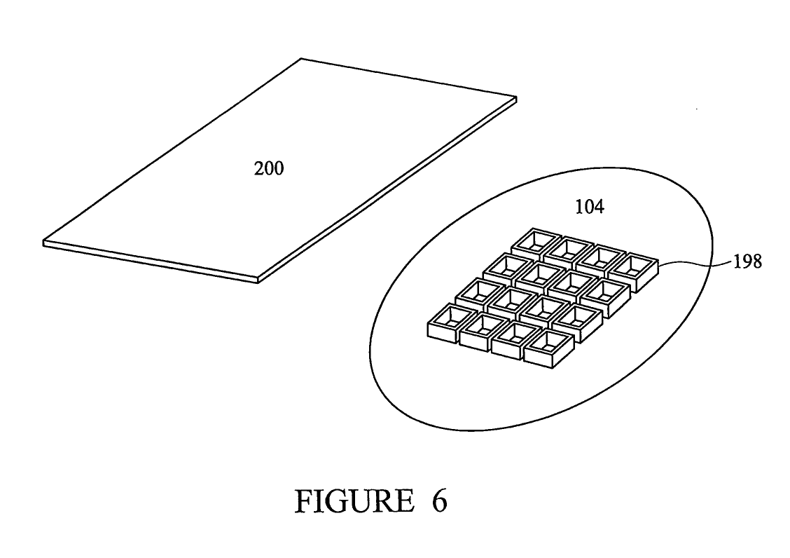

(7) FIG. 6 illustrates the wafer level chip scale packaging of integrated circuits with bleached cavity walls on substrate mounting onto transparent layer; and

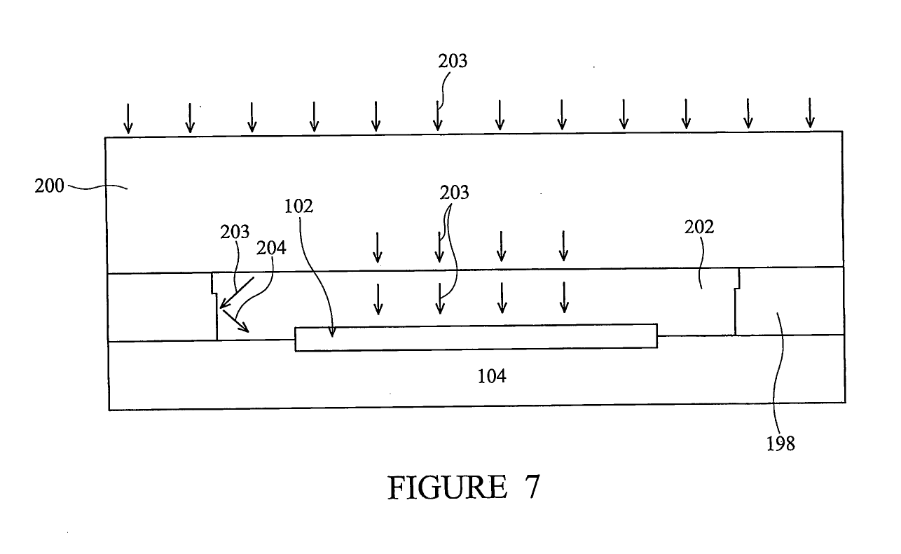

(8) FIG. 7 is the cross-sectional view of a completed wafer level chip scale package.

### DETAILED DESCRIPTION OF THE EMBODIMENTS

Initial reference is made to a schematic cross-sectional view of a color filter integrated circuit 102 on substrate 104 as illustrated in FIG. 1. The color filters may comprise of primary colors such as red, blue, and green (R/G/B color filters) or complementary colors such as cyan, magenta, and yellow (C/M/Y color filters). In addition to color filters 102, optically active complementary metal oxide semiconductor (CMOS) image sensors may also be formed on the substrate. Furthermore, although monocrystalline silicon of either N-type or P-type doping is typically the substrate of choice 104, these integrated circuits may also be formed on, for example, gallium arsenide (GaAs) or indium phosphide (InP) substrates. A photoactive region 142 is formed on substrate 104 comprising at least in part of complementary P+ or N+ doping. The photoactive regions 142 comprise photosensitive photodiodes employed within devices including but not limited to charge coupled devices (CCD), charge injection devices (CID), and optically active CMOS devices. Other active semiconductor devices may also be used in place of the photodiodes 142.

Subsequently, a patterned conductor pixel layer 144 is formed inside the color filter integrated circuit 102. The conductor pixel layer 144 serves as the first directional charge collection array in receiving the incoming signal. These signals may consist of images or light photons. The conductor pixel layer 144, consequently, stores the incoming signal by converting the images or light photons into electrical energy. Along with the conductor pixel layer 144, bond pads 146 and scribe lines 148 are also formed for ease of packaging the die on a circuit board. Electrical signals are routed from the color filter integrated circuit 102 out to the bond pads 146, while scribe lines 148 facilitate the separation of color filter integrated circuits 102 into individual devices. The first planarizing layer 150, transparent to electromagnetic spectrum radiation, is then formed using known fabrication techniques. The planarizing layer 150 planarizes or smoothes the topography of the color filter integrated circuit, thereby making subsequent fabrication steps easier.

A layer of color filters 152, separated by spacers 154, are subsequently formed. The color filters 152 and spacers 154 are arranged in unique patterns to form color filter arrays 155 having desired sensitivity and performance characteristics. In addition to separating the color filters 152, the spacers 154 also prevent scattering and reflections between neighboring color filter arrays 155. Further to this isolation, each color filter 152 may be constructed such that a single color is assigned to each pixel and that each pixel responds to only one color wavelength. A second planarizing layer 156, similar to the first planarizing layer, is subsequently formed, also serving to planarize the existing circuit topography and facilitate further processing of the circuits. Microlenses 158 are then formed on top of the color filters 152 employing methods and materials as are conventional in the art of integrated circuit fabrication to enhance optical sensitivity and provide optical flexibility as described in any of the following U.S. Pat. Nos. 6,531,266; 6,274,917; 6,242,277 and 6,171,885.

The formation of cavity walls for wafer level chip scale package is subsequently illustrated in FIGS. 2A-2C, FIGS. 3A-3C and FIG. 4. As shown in FIG. 2A, the color filter integrated circuit 102 on substrate 104 is coated with a positive photoresist 170. A photoresist is a light-sensitive chemical that is applied to the wafer utilizing a track coater spinning at high speeds. The spin speed determines the thickness of the photoresist with thicker films at low speeds and thinner films at high speeds. The positive designation indicates the tone of the photoresist and its sensitivity to light and susceptibility to being chemically washed away. The positive photoresist 170 coats about 8 to 30 microns using known integrated circuit fabrication techniques.

FIG. 2B illustrates the formation of a positive photoresist and its subsequent exposure to a light source 174 through a photomask 172 in order to harden the photoresist into a desired pattern. Typical exposures take place on a stepper or scanner and can last several seconds. The transparent parts of the photomask 172 are typically composed substantially of a quartz material that permits the light to pass through the photomask and onto the positive photoresist 170 while other areas of the photomask 172 comprise opaque chrome, which blocks the positive photoresist 170 from being exposed to the light source 174. The portion of the positive photoresist 170, which is not exposed to the light source 174, exhibits no effect, while the area that is exposed to the light source 174, subsequently undergoes a chemical reaction making it soluble in the presence of a tetra-methyl ammonium hydroxide (TMAH) base developer, a liquid chemical used for developing or dissolving photoresists.

FIG. 2C shows a cross-sectional view of the color filter integrated circuit 102 after developing or washing substrate 104 with TMAH base developer, whereby only the unexposed positive photoresist 176 remain while the area that was exposed to the light source 174 were developed or dissolved employing conventional integrated circuit fabrication techniques.

The positive photoresist pattern 176 creates a template for the subsequent formation of cavity walls as illustrated in FIGS. 3A-3C. As shown in FIG. 3A, the color filter integrated circuit 102 on substrate 104 with the remaining positive photoresist 176 is subsequently coated with a negative photoresist 190. A negative photoresist is similar to a positive photoresist in all aspects with the exception that a negative photoresist will not be chemically washed away following an exposure to the light source. The negative photoresist 190 undergoes an exposure to a light source 194 through a photomask 192 as illustrated in FIG. 3B. Upon exposure to the light source 194, a negative photoresist 190 will cross-link and harden, thereby preventing the exposed areas from being dissolved by the TMAH developer. Consequently, FIG. 3C shows a cross-sectional view of the color filter integrated circuit 102 after developing with TMAH developer. The negative photoresist 196 that was exposed to the light source 194 cross-linked and hardened, while the negative photoresist 196 that was not exposed to the light source 194 was developed or dissolved away with TMAH developer.

To produce the cavity walls 198 as illustrated in FIG. 4, the substrate 104 with the remaining (positive and negative) photoresists as shown in FIG. 3C, is then subjected to a blanket or flood exposure with an external ultraviolet (UV) light source 199. A blanket or flood exposure with an external UV light source 199, also known as bleaching, exposes all of the color filter integrated circuits 102 on substrate 104 to the UV light source 199. Upon exposure to the UV light source 199, the remaining positive photoresist 176 undergoes a chemical reaction and becomes soluble to TMAH developer. The remaining negative photoresist 196, however, exhibits the opposite trend and is further hardened or cross-linked by the exposure to the UV light source 199. Consequently, FIG. 4 shows the cross-sectional view of the color filter integrated circuits 102 on substrate 104 along with the bleached negative photoresist cavity walls 198 after subsequent exposure and developing steps. Like with negative photoresist, however, other photo-sensitive polymeric materials such as positive photoresist and benzocyclobutene (BCB) may also be bleached to transform them into absorptive cavity walls 198 with low transmittance values. Furthermore, anti-reflective dielectric materials such as silicon nitride, silicon oxide, and silicon-oxynitride may also be tweaked into highly absorptive cavity walls 198 for the purposes of this invention.

FIG. 5A illustrates the planar view of a traditional color filter device prior to packaging where the arrays 155 of color filter integrated circuits 102 are clearly arranged by pixels along with spacers 154, bond pads 146, and scribe lines 148. After the formation of the cavity walls 198 with the bleached negative photoresist 198 as shown in FIG. 5B, the spacers 154 and the bond pads 146 are no longer visible. The arrays 155 of color filter integrated circuits 102 on substrate 104 is subsequently surrounded and enclosed by the cavity walls 198, thereby making the color filter device readily available for packaging onto a transparent layer 200, such as glass-like materials including glass, sapphire, and quartz, as well as crystalline materials such as lithium niobate and lithium tantalate, as illustrated in FIG. 6.

FIG. 7 illustrates a cross-sectional view of a wafer level chip scale package structure formed using the techniques described in this application. As shown in FIG. 7, the image sensor or light detection integrated circuit 102 on substrate 104 can now be mounted to the transparent layer 200 via the bleached cavity walls 198. As a result, an evacuated or gaseous chamber 202 is created between the substrate 104 and the transparent layer 200. The chamber 202, as formed and structured here, unlike when it passes through optical epoxy, will not decay or decrease the optical sensitivity of the image sensor or light detection integrated circuit 102 to the incident light 203 coming through the transparent layer 200 and onto the circuit 102. Depending on the method and technique of packaging, the evacuated or gaseous chamber 202 may comprise of vacuum, oxygen gas, neon gas, argon gas, helium gas, nitrogen gas, air, or mixtures thereof.

Furthermore, any scattered incident light 203 will be absorbed 204 by the bleached cavity walls 198, thereby further improving the sensitivity and performance of the device. In addition, the disclosed embodiments allow for wafer level testing of these optically sensitive devices, wafer level packaging, and can result in reduced cost and improved performance of producing wafer level chip scale packages as compared to conventional packaging techniques.

It will be appreciated by those of ordinary skill in the art that the invention can be embodied in other specific forms without departing from the spirit or essential character thereof. The presently disclosed embodiments are therefore considered in all respects to be illustrative and not restrictive. The scope of the invention is indicated by the appended claims rather than the foregoing description, and all changes that come within the meaning and ranges of equivalents thereof are intended to be embraced therein.

Additionally, the section headings herein are provided for consistency with the suggestions under 37 C.F.R. § 1.77 or otherwise to provide organizational cues. These headings shall not limit or characterize the invention(s) set out in any claims that may issue from this disclosure. Specifically and by way of example, although the headings refer to a “Technical Field,” the claims should not be limited by the language chosen under this heading to describe the so-called technical field. Further, a description of a technology in the “Background” is not to be construed as an admission that technology is prior art to any invention(s) in this disclosure. Neither is the “Summary of the Invention” to be considered as a characterization of the invention(s) set forth in the claims found herein. Furthermore, any reference in this disclosure to “invention” in the singular should not be used to argue that there is only a single point of novelty claimed in this disclosure. Multiple inventions may be set forth according to the limitations of the multiple claims associated with this disclosure, and the claims accordingly define the invention(s), and their equivalents, that are protected thereby. In all instances, the scope of the claims shall be considered on their own merits in light of the specification, but should not be constrained by the headings set forth herein.

What is claimed is:

1. An optically sensitive device comprising:
a substrate; image sensor or light detection integrated circuits formed on the substrate; cavity walls about the image sensor or light detection integrated circuits, the cavity walls being substantially absorptive of incident light; and a transparent layer formed on the cavity walls and above the image sensor or light detection integrated circuits, thereby leaving open chambers defined between the transparent layer, the cavity walls, and the image sensor or light detection integrated circuits.

2. The optically sensitive device of claim 1, wherein the cavity walls are about 8 to 30 microns in height.

3. The optically sensitive device of claim 1, wherein the substrate is a semiconductor substrate.

4. The optically sensitive device of claim 3, wherein the semiconductor substrate comprises substrates selected from the group consisting of: silicon (Si); gallium arsenide (GaAs); and indium phosphide (InP).

5. The optically sensitive device of claim 1, wherein the optically sensitive device is an image sensor integrated circuit.

6. The optically sensitive device of claim 5, wherein the image sensor integrated circuit comprises devices selected from the group consisting of: charge coupled devices (CCD); charge injection devices (CID); and complementary metal oxide semiconductor (CMOS) devices.

7. The optically sensitive device of claim 1, wherein the optically sensitive device is a light detection integrated circuit.

8. The optically sensitive device of claim 7, wherein the light detection integrated circuit comprises color filters selected from the group consisting of: red/green/blue (RGB) color filters; and cyan/magenta/yellow (CMY) color filters.

9. The optically sensitive device of claim 1, wherein the cavity walls are photo-sensitive polymeric materials.

10. The optically sensitive device of claim 9, wherein the photo-sensitive polymeric materials comprises chemicals selected from the group consisting of: positive photoresist; negative photoresist; and benzocyclobutene (BCB).

11. The optically sensitive device of claim 1, wherein the cavity walls are anti-reflective dielectric materials.

12. The optically sensitive device of claim 11, wherein the anti-reflective dielectric material comprises materials selected from the group consisting of: silicon nitride; silicon oxide; and silicon-oxynitride.

13. The optically sensitive device of claim 1, wherein the transparent layer is a glass-like material.

14. The optically sensitive device of claim 13, wherein the glass-like material comprises materials selected from the group consisting of: glass; sapphire; and quartz.

15. The optically sensitive device of claim 1, wherein the transparent layer is a crystalline material.

16. The optically sensitive device of claim 15, wherein the crystalline material comprises materials selected from the group consisting of: lithium niobate; and lithium tantalate.

17. The optically sensitive device of claim 1, wherein the open chamber is evacuated.

18. The optically sensitive device of claim 17, wherein the evacuated open chamber is under vacuum.

19. The optically sensitive device of claim 1, wherein the open chamber is gaseous.

20. The optically sensitive device of claim 19, wherein the gaseous open chamber comprises gases selected from the group consisting of: oxygen; nitrogen; argon; helium; neon; air; and mixtures thereof.

21. A method of manufacturing an optically sensitive device in wafer level chip scale package comprising: a substrate; forming a plurality of image sensor or light detection integrated circuits on the substrate; forming cavity walls about the image sensor or light detection integrated circuits; bleaching the cavity walls; and forming at least one transparent layer on the cavity walls and above the image sensor or light detection integrated circuits, thereby leaving open chambers defined between the transparent layer, the cavity walls, and the image sensor or light detection integrated circuits.

22. The wafer level chip scale package of claim 21, wherein the cavity walls are about 8 to 30 microns in height.

23. The wafer level chip scale package of claim 21, whereby at least one image sensor or light detection integrated circuits, at least one transparent layer, and at least one open chamber can be individually separated from at least one image sensor or light detection integrated circuits, at least one transparent layer, and at least one open chamber, to comprise the wafer level chip scale package.

24. The wafer level chip scale package of claim 21, wherein the substrate is a semiconductor substrate.

25. The wafer level chip scale package of claim 24, wherein the semiconductor substrate comprises substrates selected from the group consisting of: silicon (Si); gallium arsenide (GaAs); and indium phosphide (InP).

26. The wafer level chip scale package of claim 21, wherein the optically sensitive device is an image sensor integrated circuit.

27. The wafer level chip scale package of claim 26, wherein the image sensor integrated circuit comprises devices selected from the group consisting of: charge coupled devices (CCD); charge injection devices (CID); and complementary metal oxide semiconductor (CMOS) devices.

28. The wafer level chip scale package of claim 21, wherein the optically sensitive device is a light detection integrated circuit.

29. The wafer level chip scale package of claim 28, wherein the light detection integrated circuit comprises color filters selected from the group consisting of: red/green/blue (RGB) color filters; and cyan/magenta/yellow (CMY) color filters.

30. The wafer level chip scale package of claim 21, wherein the cavity walls are photo-sensitive polymeric materials.

31. The wafer level chip scale package of claim 30, wherein the photo-sensitive polymeric materials comprises chemicals selected from the group consisting of: positive photoresist; negative photoresist; and benzocyclobutene (BCB).

32. The wafer level chip scale package of claim 21, wherein the cavity walls are anti-reflective dielectric materials.

33. The wafer level chip scale package of claim 32, wherein the anti-reflective dielectric material comprises materials selected from the group consisting of: silicon nitride; silicon oxide; and silicon-oxynitride.

34. The wafer level chip scale package of claim 21, wherein the transparent layer is a glass-like material.

35. The wafer level chip scale package of claim 34, wherein the glass-like material comprises materials selected from the group consisting of: glass; sapphire; and quartz.

36. The wafer level chip scale package of claim 21, wherein the transparent layer is a crystalline material.

37. The wafer level chip scale package of claim 36, wherein the crystalline material comprises materials selected from the group consisting of: lithium niobate; and lithium tantalate.

38. The wafer level chip scale package of claim 21, wherein the open chamber is evacuated.

39. The wafer level chip scale package of claim 38, wherein the evacuated open chamber is under vacuum.

40. The wafer level chip scale package of claim 21, wherein the open chamber is gaseous.

41. The wafer level chip scale package of claim 40, wherein the gaseous open chamber comprises gases selected from the group consisting of: oxygen; nitrogen; argon; helium; neon; air; and mixtures thereof.
